(19) United States
(12) Patent Application Publication
(10) Pub. No.: US 2006/0096946 A1
(43) Pub. Date: May 11, 2006

(54) Encapsulated wafer processing device and process for making thereof

(75) Inventors: Marc Schaepkens, Medina, OH (US); Takayuki Togawa, Himeji-shi (JP)

Correspondence Address: GEAM - QUARTZ;IP LEGAL, ONE PLASTICS AVENUE, PITTSFIELD, MA, 01201-3697, US

(73) Assignee: General Electric Company

(21) Appl. No.: 11/262,279

(22) Filed: Oct. 28, 2005

Related U.S. Application Data
(60) Provisional application No. 60/626,714, filed on Nov. 10, 2004.

(51) Int. Cl. H01B 13/00; C23C 16/00; C23F 1/00

(52) U.S. Cl. 216/13; 216/52; 156/345.12; 118/724

(57) ABSTRACT

A wafer processing device for use in semiconductor wafer processing applications as an Electro-Static Chuck (ESC) comprising a graphite substrate and at least one electrode pattern, wherein the grooves in the electrode pattern are filled with insulating or semiconducting material selected from a group consisting of B, Al, Si, Ga, refractory hard metals, transition metals, and rare earth metals, or complexes and/or combinations thereof, forming a substantially planar surface. The substantially planar surface is then coated with at least a semiconducting layer comprising at least one of a nitride, carbide, carbonitride or oxynitride of elements selected from a group consisting of B, Al, Si, Ga, refractory hard metals, transition metals, and rare earth metals, or complexes and/or combinations thereof.

### CROSS-REFERENCE TO RELATED APPLICATIONS

This application claims the benefits of U.S. 60/626,714 filed Nov. 10, 2004, which patent application is fully incorporated herein by reference.

### FIELD OF INVENTION

The present invention relates to a wafer-processing device primarily for use in semiconductor wafer processing equipment.

### BACKGROUND OF THE INVENTION

In the fabrication of a semiconductor device or semiconductor material, a semiconductor wafer is processed in an enclosure defining a reaction chamber with the wafer being placed adjacent to or in contact with a wafer processing device such as a resistive heater, a heating jig, or an Electro-Static Chuck (ESC) coupled to a power source. ESCs are used to clamp the semiconductor wafer electrostatically to ensure that the wafer does not move during processing; ensure good thermal contact between the wafer and the ESC—which can be either heated or cooled to a predetermined temperature; and/or apply a bias voltage to the wafer. It is often desired that a uniform clamping force is applied across the wafer to meet thermal uniformity requirements.

U.S. Pat. No. 5,343,022 discloses a heating unit for use in a semiconductor wafer processing process, comprising a heating element of pyrolytic graphite (“PG”) superimposed on a pyrolytic boron nitride base. The graphite layer is machined into a spiral or serpentine configuration defining the area to be heated, with two ends connected to a source of external power. The entire heating assembly is then coated with an outer coating of pyrolytic boron nitride (“pBN”). US Patent Publication No. 2004/0173161 discloses a heating unit coated with a material selected from the group consisting of a nitride, carbide, carbonitride or oxynitride of elements selected from a group consisting of B, Al, Si, Ga, refractory hard metals, transition metals, and combinations thereof.

One limitation of existing heaters and ESCs (collectively and used interchangeably herein, “wafer processing devices”) is with the electrode pattern that is used for clamping. The electrode pattern is typically visible in the top surface of the heating elements. In the prior art heating elements, the machined grooves in the configuration and the electrodes are conformally coated with at least one additional coating layer such as AlN, pBN, etc. The final surface exhibits the same groove pattern as the underlying electrode layer, thus in some cases resulting in some level of thermal non-uniformity in the heating surface. Additionally, the grooved surface results in a higher thermal resistance between the ESC and the wafer, potentially causing a difference in average wafer temperature and average temperature of the heating element. Furthermore, the corners or steps in the grooved surface may act as electrical stress concentration points, resulting in dielectric breakdown of the overcoat material. Lastly, the corners or steps in the grooved surface functions as a mechanical stress concentration point in the overcoat material, potentially resulting in either in delamination and/or cracking of the overcoat material.

To overcome the issue of thermal non-uniformity as a result of the presence of the grooves in the top surface, Helium is used in the prior art to fill the grooves through the application of either a backside pressure or backside flow. However, in some cases, Helium leaks out into the semiconductor process chamber and has undesirable effects on the process. Furthermore, this approach does not eliminate the electrical stress or mechanical stress limitations discussed above.

Another solution in the prior art is to apply a larger chucking voltage across the chuck for improved contact between the wafer and the top surface of the ESC on top of the electrode pattern. However, with a larger chucking voltage, there is a greater chance for electrical breakdown in the ESC at the edges of the electrode pattern. Another prior art solution is to taper the edges of the electrode pattern. However, this approach still does not resolve the thermal non-uniformity issues.

Applicants have discovered an improved heating element for use in processing semiconductor wafers that resolves the problems experienced in the prior art, i.e., thermal non-uniformity as well as electrical/mechanical stress limitations.

### SUMMARY OF THE INVENTION

The invention relates to a heating element comprising: a) a substrate body; b) a first coating material encapsulating the graphite body and forming a substantially planar surface with the patterned graphite body, the coating material comprises at least one of a nitride, carbide, carbonitride or oxynitride of elements selected from a group consisting of B, Al, Si, Ga, refractory hard metals, transition metals, and rare earth metals, or complexes and/or combinations thereof; c) a patterned electrode layer comprising an electrically conductive high melting point material comprising at least one of pyrolytic graphite, refractory hard metals, transition metals, and rare earth metals, or complexes and/or combinations thereof; d) a second coating material, that may either be the same or different from the first coating material, filling the grooves in the patterned electrode layer and forming a substantially planar surface with the patterned electrode layer, the coating material comprises at least one of a nitride, carbide, carbonitride or oxynitride of elements selected from a group consisting of B, Al, Si, Ga, refractory hard metals, transition metals, and rare earth metals, or complexes and/or combinations thereof; and e) a surface layer coating the substantially planar surface comprising the patterned electrode and coated graphite body, the surface layer comprising a semiconducting material comprising at least one of a nitride, carbide, carbonitride or oxynitride of elements selected from a group consisting of B, Al, Si, Ga, refractory hard metals, transition metals, and rare earth metals, or complexes and/or combinations thereof.

The invention further relates to a method for forming a heating element having a substantially planar surface, the method comprises the steps of: a) coating a substrate body with a overcoat layer of a nitride, carbide, carbonitride or oxynitride of elements selected from a group consisting of B, Al, Si, Ga, refractory hard metals, transition metals, and rare earth metals, or complexes and/or combinations thereof; b) applying a patterned electrode to the coated graphite body; c) leveling the patterned electrode layer; and d) encapsulating the substantially planar surface with a semiconducting material comprising at least one of nitride, a carbonitride or an oxynitride of elements selected from a group consisting of B, Al, Si, Ga, refractory hard metals, transition metals, rare earth metals, or combinations thereof.

### BRIEF DESCRIPTION OF THE DRAWINGS

FIG. 1 is a schematic diagram showing a stage progression of steps to fabricate the wafer processing device of the invention in the first embodiment of the invention;

FIG. 2 is another schematic diagram showing a second embodiment of a process to fabricate a wafer processing device of the invention;

FIG. 3 is a third schematic diagram showing yet another embodiment of a process to fabricate a wafer processing device of the invention.

FIG. 4 is a graph comparing the average temperature achieved on a wafer using a prior art wafer processing device vs. a device fabricated via a process illustrated in FIG. 1.

FIG. 5 is a series of graphs comparing the temperature variation across a wafer in a prior art device and a device fabricated via a process illustrated in FIG. 1.

FIG. 6 is schematic view illustrating the delamination problem in a prior art wafer processing device, as compared with the device of the invention with a planar surface.

FIG. 7 is schematic view illustrating the electrical failure modes in a reference wafer processing device in the prior art, as compared with the device of the invention with a planar surface.

### DETAILED DESCRIPTION OF THE INVENTION

As used herein, approximating language may be applied to modify any quantitative representation that may vary without resulting in a change in the basic function to which it is related. Accordingly, a value modified by a tern or terms, such as “about” and “substantially,” may not to be limited to the precise value specified, in some cases.

The term “wafer processing device” may be used interchangeably with and refers to a device such as a resistive heater, a heating element, a heating jig, a heating jig, a hot plate, a wafer holder, a substrate holder, or an Electrostatic Chuck (ESC) which can be used to either heat or cool a wafer to a predetermined temperature and/or serve as an electrostatic clamp.

The term “substantially continuous” means continuous or completely covered to the extent possible in a typical coating process such as chemical vapor deposition (CVD), plasma injection, thermal spray, etc.

The term “substantially planar” encompasses wafer processing device surfaces that are generally planar or flat in appearance, although optionally having minor irregularities, imperfections and/or warpage, but without affecting the generally planar or flat appearance.

The term “semiconducting materials” may be used interchangeably with “semiconducting material,” referring to both inorganic semiconducting materials and to organic semiconductors, for a non-metallic and non-insulating material whose electrical conductivity is intermediate between that of a metal and an insulator and having conductivity increases with temperature and in the presence of impurities, with volume resistivity ranging from 10⁸ to 10¹⁴ Ω-cm at room temperature. The material is further characterized that it has a statistically insignificant amount of free electrons in the conduction band at typical operating temperatures. Free electrons are present in the conduction band only at elevated temperature and/or under an electric field.

When the term “semiconducting layer” is used, it means a layer comprising a “semiconducting material.”

The invention relates to a novel wafer processing device and a novel process to fabricate a wafer-processing device. The device comprises a coated graphite body and a substantially continuous overcoat layer or layers of nitride, carbide, carbonitride or oxynitride, or mixtures thereof, forming a single structurally integral unit, and having a substantially planar surface for thermal non-uniformity and to overcome electrical/mechanical stress limitations. We now describe various embodiments of the processes to fabricate the wafer-processing device of the invention.

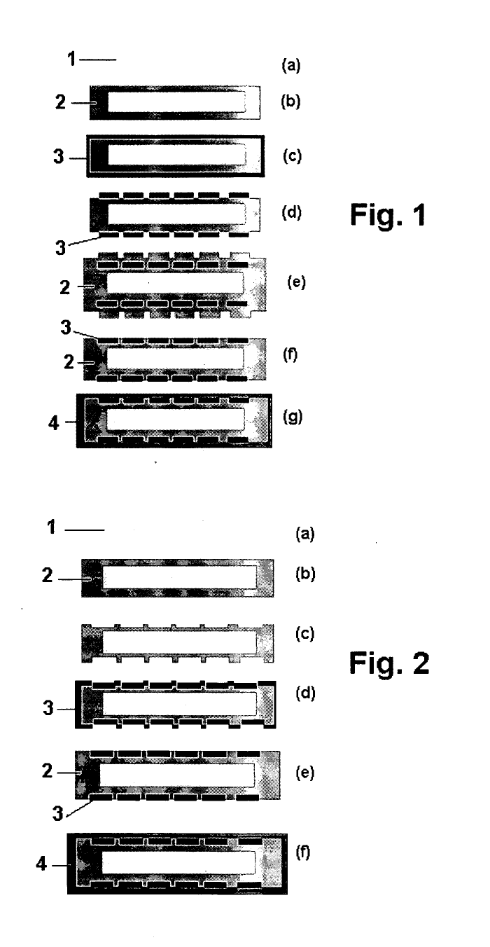

A. Process Steps: In the first embodiment of a process of the invention, the wafer processing de vice is made via a process comprising the steps illustrated in the schematic diagram of FIG. 1. In this process, a substrate 1 is provided in step (a).

In one embodiment, the substrate 1 is graphite. In a second embodiment, the substrate 1 comprises a material selected from one of quartz, hot pressed boron nitride, sintered aluminum nitride, sintered silicon nitride, sintered body of boron nitride and aluminum nitride, and a refractory metal selected from the group of molybdenum, tungsten, tantalum, rhenium, and niobium.

In step (b), a dielectric coating/insulating layer 2 is deposited onto the substrate 1. The layer 2 is of a sufficient thickness to provide the desired corrosion resistance as well as structural integrity and support in the machining step. The layer 2 further provides electrical insulation and sufficiently high breakdown voltage in the final application. In one embodiment, the layer 2 has a thickness from about 0.001 to 0.20″. In a second embodiment, from about 0.005 to 0.020″. In a third embodiment, from about 0.01 to 0.10″. The layer 2 comprises at least one of a nitride, carbide, carbonitride or oxynitride of elements selected from a group consisting of B, Al, Si, Ga, refractory hard metals, transition metals, and rare earth metals, or complexes and/or combinations thereof. Examples include pyrolytic boron nitride, aluminum nitride, titanium aluminum nitride, titanium nitride, titanium aluminum carbonitride, titanium carbide, silicon carbide, and silicon nitride. In one embodiment, the coating layer 2 comprises pyrolytic boron nitride (pBN). In a second embodiment, the layer 2 comprises AlN. In a third embodiment, a complex of AlN and BN. In yet a fourth embodiment, the coating layer 2 comprises an aluminum nitride wherein a small amount of Y₂ O₃ is added, e.g.. in amount of 5 wt % relative to 100 wt % of aluminum nitride. Both pBN and AlN have excellent electrically insulating and thermally conducting properties and can be easily deposited from the gaseous phase. They also have a high temperature stability.

In step (c), an electrically conducting coating layer 3 is applied on top of the dielectric coating layer for subsequent forming into an electrode. In one embodiment, the coating layer 3 comprises pyrolytic graphite (PG). In yet another embodiment, the electrode layer 3 comprises pyrolytic graphite doped with boron and/or boron carbide of 0.001-30% by weight in terms of boron concentration.

Pyrolytic graphite is essentially highly oriented polycrystalline graphite produced by high temperature pyrolysis of a hydrocarbon gas such as methane, ethane, ethylene, natural gas, acetylene and propane. The layer 3 can be applied via any process known in the art, including physical vapor deposition (PVD) and chemical vapor deposition (CVD) processes, for a thickness ranging from 0.001 to 0.01″. In another embodiment, for a thickness of 0.005 to 0.10″.

In step (d), the PG layer 3 is patterned into a pre-determined pattern by a process known in the art, e.g., etching, sandblasting, machining, etc., forming grooves in the PG coating. The pattern extends down to or into the underlying insulating PG coating layer 3 so as to form a resistance heating element or an electrical flow path, e.g., a spiral pattern, a serpentine pattern, a helical pattern, a zigzag pattern, a continuous labyrinthine pattern, a spirally coiled pattern, a swirled pattern, a randomly convoluted pattern, and combinations thereof.

In step (e), a second dielectric coating/insulating layer 2 is deposited onto the patterned PG layer 3. In one embodiment, the coating layer 2 is a deposition of a conformal coating with a consistent thickness that closely conforms to the shape and contours of the entire patterned PG substrate. The second layer can be of the same or different material from the first layer, i.e., comprising at least one of a nitride, carbide, carbonitride or oxynitride of elements selected from a group consisting of B, Al, Si, Ga, refractory hard metals, transition metals, and rare earth metals, or complexes and/or combinations thereof. In one embodiment, the second layer 2 comprises pBN. In another embodiment, the 2^{nd} layer has a thickness that is at least as high as the depth of the grooves into the PG patterned coating layer. In yet another embodiment, the coating dielectric layer comprises a composition of pyrolytic boron nitride (pBN) and a carbon dopant in an amount of less than about 3 wt % such that its electrical resistivity is smaller than 10¹⁴ Ω-cm.

In step (f), the second coating layer, e.g., a pBN layer, is polished or planarized either chemically, mechanically, or via chemical-mechanical polishing. In this planarization process, only the top surface material is removed/polished and not the material in the grooves between the PG patterns.

In step (g), a semiconducting layer 4 is applied onto the flat surface comprising both the PG and insulator material. for a planar surface onto which a wafer can be chucked (e.g., through the use of the Johnson-Rahbeck effect). The semiconducting layer may be of the same or different material from the second coating material, i.e., comprising at least one of a nitride, carbide, carbonitride or oxynitride of elements selected from a group consisting of B, Al, Si, Ga, refractory hard metals, transition metals, and rare earth metals, or complexes and/or combinations thereof.

In one embodiment of the invention, the semiconducting layer 4 is carbon doped pyrolytic boron nitride (CpBN), having an electrical resistivity of<5×10¹³ ohm-cm. Carbon doped pBN is disclosed in U.S. Pat. No. 5,693,581, which reference is incorporated herein by reference. In another embodiment, the semiconducting layer 4 is a CpBN layer having 1-20 wt. % in terms of carbon concentration. In yet another embodiment, the semiconducting layer comprises pBN doped with carbon and silicon in an amount of 1 to 10 wt. % for a volume resistivity of 10⁸ to 10¹⁴ Ω-cm at room temperature. In another embodiment, a volume resistivity of 10⁸ to 10¹² Ω-cm.

In one embodiment of the invention, the semiconducting layer comprises aluminium nitride doped with at least one of carbon, oxygen, magnesium, and mixtures thereof, for a volume resistivity of 10⁸ to 10¹⁴ Ω-cm at room temperature. In another embodiment, the semiconducting layer comprises a doped aluminium oxynitride. The coating of AlN is disclosed in U.S. Pat. Nos. 5,777,543 and 5,668,524, which references are incorporated herein by reference. In one embodiment, the doped aluminum nitride semiconducting surface layer has a volume resistivity of less than 10¹⁰ Ω-cm at room temperature. In yet another embodiment, the doped aluminium nitride contains 0.005 to 30 atomic % of an element selected from Group 4b and Group 6b of the periodic table for a volume resistivity of less than 10¹⁰ Ω-cm.

In the second embodiment of a process of the invention, the wafer processing device is made according to the process illustrated in schematic diagram of FIG. 2. In this process, the first two steps (a) and (b) are similar to that of the first embodiment. The materials for use in the layers in the steps are similar to those described in the first embodiment of the process of the invention.

In the next third step (c), the coating/insulator coating layer 2, e.g., comprising pBN, is patterned into a pre-determined grooved pattern by a process known in the art, e.g., etching, sandblasting, machining, et.

In the fourth step (d), the patterned layer, e.g., the pBN layer 2, is conformally coated with a conducting material 3, such as pyrolytic graphite (PG). In the fifth step (e), the PG conducting electrode layer 3 is planarized in a damascene fashion, i.e.., only polishing the top surfaces and not the material in the recessed areas, until the underlying pBN surfaces show in the areas between the PG electrodes. Lastly in step (f), a final semiconductive layer 4, e.g., comprising CpBN, is applied onto the flat/polished surface of step 5, to form a planar surface to which a wafer can be chucked.

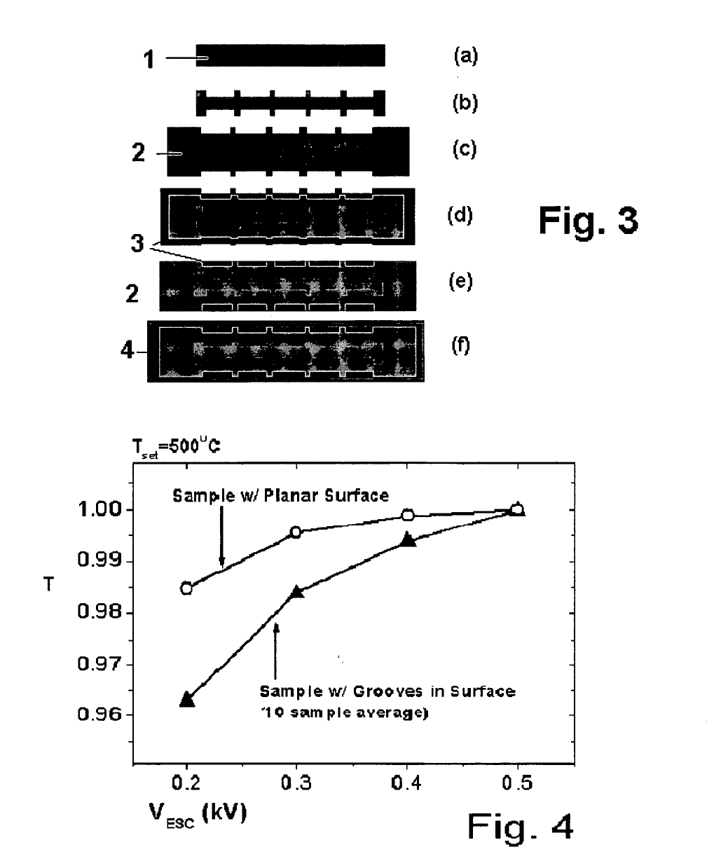

The novel wafer processing device may made via another alternative embodiment as illustrated in FIG. 3. In the first step (a), a substrate 1 comprising a material such as graphite is provided. In the next step, the substrate 1 is machined to form electrode patterns using a process known in the art, e.g., etching, sandblasting, machining, etc. In the subsequent step (c), an insulating/coating layer 2 comprising a material such as PBN is applied onto the patterned electrode. In one embodiment, the pBN base coat 2 is conformally applied for a consistent thickness that closely conforms to the shape and contours of the entire patterned graphite substrate.

In step (d), a conductive layer 3 such as PG is deposited onto the pBN base coat layer 2. In one embodiment, the conductive layer 3 is conformally deposited for a thickness that closely conforms to the shape of the pBN base coat layer 2. In step (e), the conductive layer 3 is planarized until a relatively flat surface is obtained. The conductive PG layer 3 is planarized using any process known in the art, e.g., etching, sandblasting, machining, etc.

In step (f), a semiconductive layer 4 comprising a material such as CpBN is applied onto the flat/polished surface for a planar Surface to which a wafer can be chucked.

B. Detailed Step Description: In following the steps of any of the above three embodiments, a wafer processing device having relatively flat or planar surface can be made. The selection of either the first, second, or third embodiment to manufacture the wafer processing device of the invention depends on factors such as availability/capability of available equipment for use in machining, grooving, coating, etc., the various layers in the device of the invention, as well as the supply/properties of the materials for use as the insulating/semiconductive layers in the device of the invention.

In the first embodiment of the process of the invention, the flat or planar surface is achieved by polishing the second insulating coating, e.g. made of PBN material. On the other hand, in embodiments 2 and 3, the planar surface is achieved by polishing the PG material. Due to the hardness of the PG material, it may be more difficult to remove PG than with a typical material for use as a second insulating layer, e.g., pBN. Also with the first embodiment, one has more flexibility of selecting different insulating coating materials, e.g., pBN, doped pBN, AlN, etc. for use in filling the gap (grooves) between the PG patterns as in step (3) of the first embodiment. This allows for optimization of thermal & electrical properties of the underlying basecoat material and the gap fill materials such as pBN, providing a wafer processing device with additional mechanical and/or electrical benefits.

It should be noted that the first embodiment of the invention can be used to “recycle” or “refurbish” the prior art ESC with grooved surfaces into improved ESC having planar surface. Namely, one can polish back the existing overcoat, e.g., CpBN layer, on existing wafer processing devices and use this layer as the gap fill coating for the patterned graphite electrodes. After the overcoating layered is polished back or flattened to become gap fillers, new final overcoating can be applied to yield a “refurbished” device having a flat surface.

In another embodiment of a refurbishing process, the outermost overcoat layer of a prior art device is removed entirely (or to the desired extent), exposing the PG electrode pattern. A second insulating layer (a pBN layer, or a layer comprising other insulator or semiconducting/resistive materials) is applied covering the PG electrode layers. The second layer may be applied in the form of conformal coating layer, conforming to the shape and contours of the patterned graphite layer. In the next step, the second insulating layer is polished back/planarized in a damascene fashion until it is level with the PG pattern. Finally, a semiconducting material, e.g., a CpBN overcoat, is applied for an ESC with a flat surface.

In one embodiment wherein the wafer processing device is used as a heating element, after the deposition of the semiconductive layer 4, electrical contacts are machined through the top layer 4 to expose the conductive graphite layer 3 at certain contact locations for connection to an external power source. Alternatively, electrical contact extensions can be machined into the graphite layer 3 at the outset before the final coating process, or added prior to the over coating operation. In one embodiment of the invention, graphite electrical extension posts can be connected to the patterned electrical path and coated with the over-coating material 4.

In one embodiment of the invention, each of the first and second coating/insulating layers 2 and the semiconductor layer 4 has a thickness varying from 0.001 to 0.20″. In a second embodiment, from about 0.001 to 0.020″. In a third embodiment, from about 0.01 to 0.10″. In a second embodiment, at least one the layers has a thickness of 0.004 to 0.05″. In another embodiment, at least one of the layers has a thickness of less than about 0.02″. In yet another embodiment, at least one the layers is a substantially continuous surface layer having a thickness in the range of about 0.01 ″ to 0.03″.

Different methods can be used to deposit the coating/insulating/semiconductive layer or layers onto the graphite body/substrate. In one embodiment, at least one of the layers can be applied through physical vapor deposition (PVD), wherein the coating material, e.g. boron nitride and/or aluminum nitride is/are transferred in vacuum into the gaseous phase through purely physical methods and are deposited on the surface to be coated. In another embodiment, the coating material is deposited onto the surface under high vacuum, wherein it is heated to transition either from the solid via the liquid into the gaseous state or directly from the solid into the gaseous state using electric resistance heating, electron or laser bombardment, electric arc evaporation or the like. Sputtering can also be used, wherein a solid target which consists of the respective coating material is atomized in vacuum by high-energy ions, e.g. inert (or reactive) gas ions, in particular argon ions, with the ion source being e.g. inert gas plasma. Finally, a target which consists of the respective coating material can also be bombarded with ion beams under vacuum, be transferred into the gaseous phase and be deposited on the surface to be coated.

In one embodiment, the above-mentioned methods can be combined and at least one of the layers can be deposited e.g. through plasma-supported or plasma-enhanced vapor deposition. Alternatively in one embodiment of the invention or as an additional coating layer, at least one of the layers can be deposited through chemical vapor deposition (CVD). In contrast to the PVD methods, the CVD method has associated chemical reactions. The gaseous components produced at temperatures of approximately 200 to 2000° C. through thermal, plasma, photon or laser-activated chemical vapor deposition are transferred, possibly with an inert carrier gas, e.g. argon, usually at sub-atmospheric pressure, into a reaction chamber in which the chemical reaction takes place. The solid components thereby formed are deposited onto the substrate to be coated. The volatile reaction products are exhausted along with the carrier gas.

In yet another embodiment of the invention, at least one of the layers can also be deposited using thermal injection methods, e.g. by means of a plasma injection method. Therein, a fixed target is heated and transferred into the gaseous phase by means of a plasma burner through application of a high-frequency electromagnetic field and associated ionization of a gas, e.g. air, oxygen, nitrogen, hydrogen, inert gases etc. The target may consist, e.g. of boron nitride or aluminum nitride and be transferred into the gaseous phase and deposited on the graphite body to be coated in a purely physical fashion. The target can also consist of boron and be deposited as boron nitride on the surface to be coated through reaction with the ionized gas, e.g., nitrogen, or ammonia.

In another embodiment, a thermal spray process is used, i.e., a flame spray technique is used wherein the powder coating feedstock is melted by means of a combustion flame, usually through ignition of gas mixtures of oxygen and another gas. In another thermal spray process called arc plasma spraying, an electric arc creates an ionized gas (a plasma) that is used to spray the molten powdered coating materials in a manner similar to spraying paint. In yet another embodiment, the coating material is applied as a paint/spray and sprayed onto the graphite body with an air sprayer.

In another embodiment for a relatively “thick” coating layer, i.e., of 0.03 inches or thicker, the coating material is applied simply as a liquid paint and then dried at sufficiently high temperatures to dry out the coating. In one embodiment wherein BN is used as a coating, the BN over-coated graphite structure is dried at a temperature of at least 75° C., and in one embodiment, of at least 100° C. to dry out the coating.

In one embodiment of the invention wherein pBN is used for a coating layer, the pBN is applied via a CVD process as described in U.S. Pat. No. 3,182,006, the disclosure of which is herein incorporated by reference. In the process, vapors of ammonia and a gaseous boron halide such as boron trichloride (BCl₃) in a suitable ratio are used to form a boron nitride deposit on the surface of the graphite base 10.

In one embodiment, after the final semiconductive coating is applied by one of the methods described above, the coated graphite structure is heated to a temperature of at least 500° C. to further bond various coating layers onto the graphite body.

The forming of a pattern in the solid graphite body, the PG layer, or the coating layer may be done by techniques known in the art, including but not limited to micro machining, micro-brading, laser cutting, chemical etching, or e-beam etching. The pattern may be defined for example, by a removable mask or tape. Other masking techniques include the use of dissolvable protective coatings, e.g., photoresist. Patterned application allows for controlled heating in localized areas of the graphite body. The pattern may be of various sizes and shapes for defining an electrical flow path for at least one zone of an electrical heating circuit. In one embodiment, the flow path is of a spiral or serpentine geometrical pattern. In a second embodiment, the flow path is a helical pattern. In a third embodiment, the path is of a spirally coiled pattern. In a fourth embodiment, the path is of a zigzag pattern. In a fifth embodiment, the flow path is of a continuous labyrinthine pattern. In another embodiment, the flow path is a randomly convoluted pattern. In yet another embodiment, the path is of a swirled pattern.

The planarization of the PG layer and/or the insulation layer in the steps in any of the embodiments of the invention can be done either chemically, mechanically, or via chemical-mechanical polishing processes known in the art such as grinding, milling, etc. In one embodiment, the planarization is done until the surface variation (from the lowest—highest points on the surface) is 100 microns or less. In another embodiment, the planarization is carried out until the surface is ground relatively flat with a surface variation of less than 50 microns.

The surface of the wafer-processing device of the invention is substantially planar without any exposed graphite surfaces for hermetically sealing the patterned heat-generating graphite resistor body, other than those surfaces necessary for electrical connections. In one embodiment, the substantially planar (relatively flat or planar) surface is defined as having surface variations, i.e., from the highest point to the lowest point on the device surface, of less than 200 microns. In a second embodiment, the device has a surface variation of less than 100 microns. In a third embodiment, a surface variation of less than 50 microns.

The substantially planar surface of the device helps prevent short circuits and electrical changes from occurring, and insures a substantially continuous surface free from graphite dust and particles. There may be however, certain holes or surface features on the top coated surface, for the reason that in most practical wafer processing applications, these features may be required for lifting devices or mounting locations.

### EXAMPLES

Examples are provided herein to illustrate the invention but are not intended to limit the scope of the invention.

### Example 1

In this first example, an electrostatic chuck (ESC) is made by the process of the first embodiment is compared to a prior art ESC. The prior art ESC having surface grooves is commercially available from General Electric Company (“GE”) of Kozuki, Japan.

The ESC is constructed by first depositing a pyrolytic boron nitride base coating layer on a graphite substrate by passing BCl₃, NH₃ in a graphite vacuum furnace based CVD reactor. Reactant gases are introduced into a heated chamber (heated to a temperature in the range of 1600°-1900° C.) within a water-cooled steel vacuum chamber. The graphite body is placed between injectors through which reactant gases flow into the heated chamber. Water-cooled coaxial injectors are used. Temperature is monitored by an optical pyrometer. Pressure is monitored by a vacuum transducer.

After the pyrolytic boron nitride base coating layer has been deposited and machined to a certain thickness and flatness, a conducting pyrolytic graphite (PG) coating of about less than 100 μm thick is applied on top of the PBN coating also via a CVD process using methane (CH₄). The PG layer is machined down to the underlying insulating PBN coating to form grooves in a zig zag serpentine pattern.

After the PG layer is patterned and machined to certain thickness and flatness, a second PBN coating with a thickness at least as high as the depth of the grooves into the PG coating, also via a CVD process. The second PBN coating is polished back in a damascene fashion until the electrode top surfaces show, while the original grooves now contain PBN material. The structure at this point thus shows a relatively flat or planar surface comprising both PG and PBN areas.

In the final step, a carbon doped PBN coating (CPBN) of a thickness between 100 to 200 microns is applied on top of the truly flat surface, also via a CVD process. In the CpBN deposition process, CH₄ is introduced along with BCl₃ and NH₃ at feed rates adjusted for the carbon concentration in the PBN to be kept at about 3 wt. % or less (by adjusting the C/B ratio and N/C ratio in the feed gases, specifically the rates of CH₄ relative to BCl₃ and NH₃).

The ESC of the invention having a flat wafer-chucking surface is compared with an ESC of the prior art having grooves in the surface. In operation, DC voltage is applied to the electrode on the chuck side. In a semiconductor processing operation, it is desirable to achieve an average wafer temperature at the lowest possible chucking voltage, since this reduces the potential for electrical breakdown of the chuck and allows the use of lower cost, lower voltage power supplies, and also allows for faster dechucking of a wafer after processing thus increasing throughput.

FIG. 4 is a graph comparing the average temperature data obtained from two similar wafers as a function of wafer-clamping voltage (V_{esc}) at ESC set-point temperature of 500° C. One wafer was in contact with the ESC of the invention having a planar surface, the other wafer was in contact with a ESC of the prior art having grooves in the surface. The sensing wafers were equipped with a plurality of thermocouples, and the average temperatures of the prior art wafer were from 10 samples. In the graph, the average temperatures at the various wafer-clamping voltages are normalized to the average wafer temperature measured at a V_{esc} of 0.5 kV. As illustrated in the Figure, in the ESC of the invention, the average wafer temperature at V_{esc} of 0.2, 0.3 and 0.4 kV is relatively close to the value at 0.5 kV. On the other hand, the reference prior art ESC with grooves in the surface shows significantly lower average temperatures at 0.2, 0.3 and 0.4 kV that is achieved at 0.5 kV.

### Example 2

In this Example, thermal uniformity data is obtained from both the ESC of the invention and reference ESC in the prior art (with grooved surface as commercially available from GE in Strongsville, Ohio). The ESC in this Example is made the same way as in Example 1.

Thermal uniformity data refers to the delta temperature across the wafer, or Tmax-Tmin. In operation, it is desirable to have a low “delta temperature” across the wafer for even heating and quality product control.

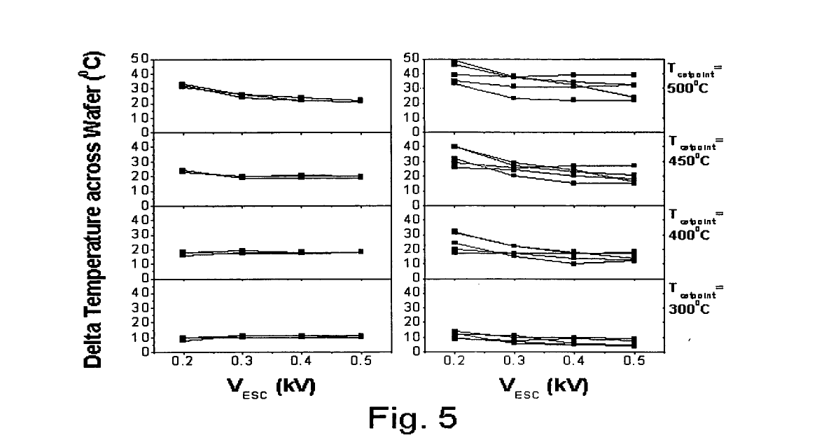

The results of the experiments are as illustrated in FIG. 5. The Figure compares data obtained from the ESC of the invention having truly planar surface (data LEFT of the Figure, with the same sample measured 3 times), and data from the prior art ESC (data on the RIGHT of the Figure, from 5 reference samples with each measured 1 time). As illustrated in the Figure, at higher ESC set-point temperatures and low wafer-chucking voltages, the ESC of the invention with the planar surface outperforms the typical reference samples of the prior art for a lower delta temperature across the wafer.

### Example 3

In this Example, the ESC of the invention is compared with a prior art ESC (with grooved surface commercially available from GE) from the mechanical stress reference point. It is known in the art that delamination occurs in ESC as result of compressive stress due to thermal expansion mismatches. This stress is elevated at raised steps in a ESC surface.

In this example to demonstrate the improved performance of the ESC of invention, 488 prior art ESC samples are compared with 18 ESC of the invention. The ESC in this Example is constructed in the same way as the ESC in Example 1.

A number of the prior art samples show delamination at the edges of the underlying PG pattern after the substrates came out of the CVD furnace. However, the ESC of the invention having a substantially flat surface does not exhibit delamination at those locations.

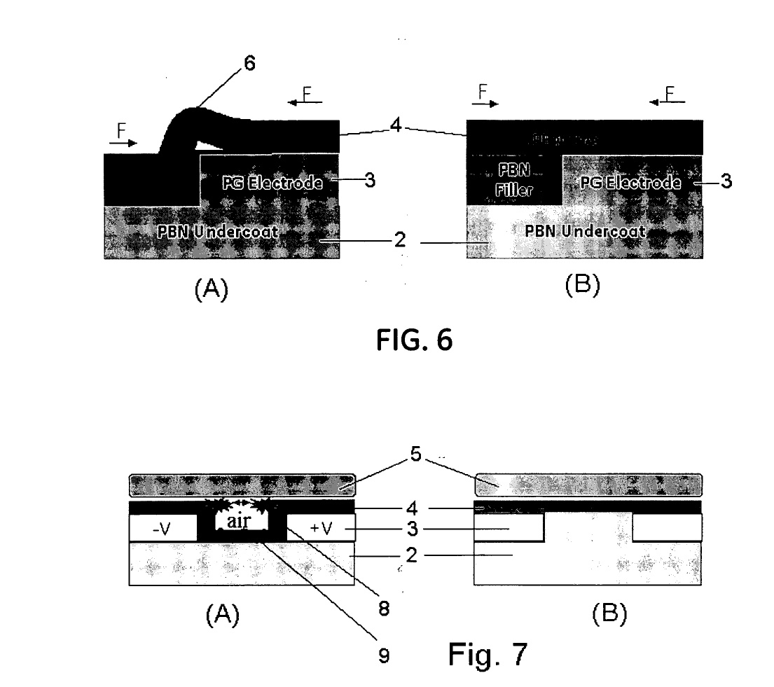

FIG. 6 is a schematic diagram illustrating a cross section of the ESC of the invention, as compared with the cross section of the ESC of the prior art in operation. In this study, 188 out of 488 prior art ESC samples developed delamination defects, while none of the ESC of the invention developed delamination.

Table 1 shows the 95% confidence intervals (upper confidence level UCL and lower confidence level LCL) around the probability of developing delamination for both sets of samples: a) 488 ESC from the prior art, and b) 18 samples of the invention with planar/flat surface. The probability of developing delamination is indicated as the number of defects per million opportunities (DPMO). The data shows that the improved performance of the ESC of invention, i.e. the reduction of probability of developing delamination, is statistically significant since the confidence intervals do not overlap. It should be noted that the ESC of the invention and the prior art ESC were produced within approximate time period and using the same CVD coating process for the various coating layers, e.g., pBN and CpBN.

TABLE 1

DPMO for Delamination

| | 95% LCL | 95% UCL |
|---|---|---|
| Standard Heater | 205929 | 294071 |
| Flat Surface Heater | 0 | 153318 |

### Example 4

In this Example, the ESC of the invention constructed as in the previous examples was compared with the ESC of the prior art from an electrical stress concentration viewpoint. The ESC of the prior art was from General Electric Company in Strongsville, Ohio.

FIG. 7 is a schematic diagram illustrating and comparing the ESC of the invention and an ESC of the prior art. Delamination was experienced shortly in operation with the ESC with the prior art. With the delamination and or gaps between the electrodes, the probability for a breakdown 8 in voltage is expected to increase for the prior art ESC, causing electrical failure modes. There is less of an opportunity for electrical failure modes in the ESC of the invention with a planar surface. As illustrated in the Figure, an insulator material like PBN fills in the gaps between the electrodes. As a result of the insulating material in the gap of the ESC of the invention, the opportunity for surface voltage drop due to leakage 9 between oppositely charged electrodes in a bi-polar ESC is expected to be less as a result of the presence of insulating material in the gaps.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

All citations referred herein are expressly incorporated herein by reference.

What is claimed is:

1. A wafer processing device having a top surface on which a wafer can be mounted and a bottom surface, the device comprising
a substrate body, the substrate body comprising a material selected from graphite, hot-pressed boron nitride, quartz, sintered aluminum nitride, and molybdenum;
a coating layer encapsulating the graphite body, the coating layer comprises at least one of a nitride, carbide, carbonitride or oxynitride of elements selected from a group consisting of B, Al, Si, Ga, refractory hard metals, transition metals, and rare earth metals, or complexes, and combinations thereof;
an electrically conductive electrode having grooves configured in a pattern, wherein the grooves in the electrode pattern are filled with a material comprising at least one of a nitride, carbide, carbonitride or oxynitride of elements selected from a group consisting of B, Al, Si, Ga, refractory hard metals, transition metals, and rare earth metals, or complexes and combinations thereof, and wherein the patterned electrically conductive electrode forming a substantially planar surface with the coating layer on at least the top surface of the device;
a surface layer disposed on the substantially planar surface comprising the patterned electrically conductive electrode filled grooves and the coating layer, the surface layer comprising a semiconducting material selected from at least one of a nitride carbide, carbonitride or oxynitride of elements selected from a group consisting of B, Al, Si, Ga, refractory hard metals, transition metals, and rare earth metals, complexes and combinations thereof.

2. The wafer processing device of claim 1, wherein the electrically conductive electrode having grooves configured in a pattern for an electrical flow path defining at least one zone of an electrical heating circuit on at least the top surface of the device, wherein the electrical circuit comprising terminal ends for terminals to be electrically connected to the electrical flow path.

3. The wafer processing device of claim 1, wherein the surface layer comprises a carbon doped pyrolytic boron nitride (CpBN).

4. The wafer processing device of claim 3, wherein the carbon doped pyrolytic boron nitride (CpBN) contains 0.1-20 wt. % of carbon concentration.

5. The wafer processing device of claim 4, wherein the carbon doped pyrolytic boron nitride (CpBN) contains less than 10 wt. % carbon.

6. The wafer processing device of claim 1, wherein article of claim 1, wherein the semiconducting surface layer has a volume resistivity of 10⁸ to 10¹⁴ Ω-cm at room temperature.

7. The wafer processing device of claim 1, wherein the substrate body comprises a graphite material, the coating layer comprises pyrolytic boron nitride (pBN), the electrically conductive electrode comprises pyrolytic graphite, and the grooves in the electrode pattern are filled with pBN.

8. The wafer processing device of claim 1, wherein the substantially planar surface comprising the patterned electrically conductive electrode and the insulating or semiconducting material filling the grooves in the patterned electrode is formed by:
coating the patterned electrically conductive electrode with a layer comprising at least one of an insulating material or a semiconductive material, comprising at least one of a nitride, carbide, carbonitride or oxynitride of elements selected from a group consisting of B, Al, Si, Ga, refractory hard metals, transition metals, and rare earth metals, or complexes and combinations thereof;
planarizing the coating layer until the coating layer becomes substantially even with the patterned electrically conductive electrode, forming a substantially planar surface.

9. The wafer processing device of claim 8, wherein the patterned electrically conductive electrode is coated with a conformal layer having a thickness conforming to the grooves of the patterned electrically conductive electrode.

10. The wafer processing device of claim 8, wherein the material filling the grooves in the patterned electrode is a semiconducting material comprises at least one of a nitride, carbide, carbonitride or oxynitride of elements selected from a group consisting of B, Al, Si, Ga, refractory hard metals, transition metals, and rare earth metals, or complexes and combinations thereof.

11. The wafer processing device of claim 8, wherein the patterned electrode comprises a pyrolytic graphite (PG), and the material filling the grooves in the PG patterned electrode comprises pyrolytic boron nitride.

12. The wafer processing device of claim 8, wherein the surface layer comprises aluminum nitride containing 0.005 to 30 atomic % of an element selected from Group 4b and Group 6b of the periodic table for a volume resistivity of less than 10¹⁰ Ω-cm.

13. The wafer processing device of claim 8, wherein the surface layer comprises pyrolytic boron nitride (CpBN) containing 0.1 to 20 wt. % of carbon concentration.

14. The wafer processing device of claim 8, wherein at least one of the coating layer encapsulating the graphite body and the semiconducting surface layer has a thickness of 50 micrometer to 500 micrometer.

15. A method for forming a wafer processing device having a top surface on which a wafer can be mounted and a bottom surface, the method comprising the steps of:
encapsulating a substrate body with a coating layer comprising a material selected from graphite, hot-pressed boron nitride, quartz, sintered aluminum nitride, and molybdenum with a coating layer comprising at least one of a nitride, carbide, carbonitride or oxynitride of elements selected from a group consisting of B, Al, Si, Ga, refractory hard metals, transition metals, and rare earth metals, or complexes and/or combinations thereof;
forming an electrode pattern with grooves on the encapsulated substrate body;
leveling the grooves with one of an insulating or semiconducting material comprising at least one of a nitride, carbide, carbonitride or oxynitride of elements selected from a group consisting of B, Al, Si, Ga, refractory hard metals, transition metals, and rare earth metals, or complexes and combinations thereof, for a substantially planar surface comprising the patterned groove and the insulating or semiconducting material on at least the top surface of the device;
disposing on said substantially planar surface a surface layer comprising a semiconducting material selected the group of a nitride, carbide, carbonitride or oxynitride of elements selected from a group consisting of B, Al, Si, Ga, refractory hard metals, transition metals, and rare earth metals, and complexes, and combinations thereof.

16. The method of claim 15, wherein the grooves defines an electrical flow path for an electrical heating circuit on at least the top surface of the device, the electrical circuit comprising terminal ends for terminals to be electrically connected to the electrical flow path.

17. The method of claim 15, wherein the grooves are leveled by:
coating the patterned electrode with a layer of a semiconducting material comprising at least one of a nitride, carbide, carbonitride or oxynitride of elements selected from a group consisting of B, Al Si, Ga, refractory hard metals, transition metals, and rare earth metals, or complexes and combinations thereof;
planarizing the coating layer until the coating layer becomes substantially even with the patterned electrode, forming a substantially planar surface with the patterned electrode.

18. The method of claim 17, wherein the patterned electrically conductive electrode is coated with a conformal layer having a thickness conforming to the grooves of the patterned electrically conductive electrode.

19. The method of claim 18, wherein the deposition of the conformal coating layer is made using a chemical vapor deposition process.

20. The method of claim 15, wherein the substrate body comprises a graphite material, the coating layer comprises pyrolytic boron nitride (pBN), the electrically conductive electrode comprises pyrolytic graphite, the grooves in the electrode pattern are filled with pBN, and the surface layer comprises a carbon doped pyrolytic boron nitride (CpBN).

21. The method of claim 20, wherein the carbon doped pyrolytic boron nitride (CpBN) surface contains less than 10 wt. % of carbon.

22. The method of claim 21, wherein the surface semiconducting layer has a volume resistivity of 10⁸ to 10¹⁴ Ω-cm at room temperature.
